(19) United States
(12) Patent Application Publication
(10) Pub. No.: US 2026/0150619 A1
(43) Pub. Date: May 28, 2026

(54) SYSTEM AND METHOD FOR PLANAR MOTOR INTEGRATED WAFER HANDLER

(71) Applicant: Raj Subramanya, Oldsmar, FL (US)

(72) Inventor: Raj Subramanya, Oldsmar, FL (US)

(21) Appl. No.: 18/956,907

(22) Filed: Nov. 22, 2024

(51) Int. Cl. H01L 21/677; H01L 21/67

(52) U.S. Cl. CPC H10P 72/3302; H10P 72/0464; H10P 72/3304

(57) ABSTRACT

A system for wafer handling for semiconductor manufacturing, including at least one vacuum transfer chamber; at least one planar motor mover unit positioned inside the at least one vacuum transfer chamber; an End-effector attached to the least one planar motor mover unit. The End-effector is configured to travel in any direction inside of the at least one vacuum transfer chamber.

### FIELD OF DISCLOSURE

The present disclosure generally relates to wafer transportation in the vacuum transfer modules, and more particularly, to a system and method for wafer handling for semiconductor manufacturing that integrates planar motor technology directly into vacuum transfer chambers.

### BACKGROUND

Currently, wafer transportation in the vacuum transfer modules of standard substrate handlings systems are made of large vacuum chamber where in the middle lies a “vacuum” robot. This robot is typically designed to handle movement of the substrate from atmospheric load locks into the process modules and back.

Robots are generally configured as a Selective Compliance Assembly Robot or “SCARA” style robot. That means that the robots have multiple arm segments that swing over themselves to move the substrates in a linear fashion. This movements require the robots to be based in a fixed location and the robot's arms move out from that location. The chamber must be designed larger to accommodate the extra height of the robotic arms leading to costs and lower vacuum performance.

The conventional robotic system configuration allows for only one wafer being moved at a time. Thus, the systems cannot be designed linearly or expanded without the need for multiple robots and some sort of hand off between the two robots (using a buffer station) where the substrate is dropped off and another robot picks it up. This leads to limits on the amount of process modules that can be attached, large waste of space, increased cost, heavily reduced throughput. Further, the systems cannot be custom configured to maximize density inside of the cleanroom where floorspace is at a premium.

The conventional multiple robots by their nature must have moving parts in the arms that are residing inside of the vacuum chamber. These robots then generate particles due to the inherent wear of moving parts. This means that the robots must also be maintained to replace wearable items like belts pulleys and bearings on an emergency or preventative maintenance plan leading to tool downtimes which incur additional costs.

Accordingly, a system and method for wafer handling for semiconductor manufacturing that integrates planar motor technology directly into vacuum transfer chambers are desired.

### BRIEF OVERVIEW

This brief overview is provided to introduce a selection of concepts in a simplified form that are further described below in the Detailed Description. This brief overview is not intended to identify key features or essential features of the claimed subject matter. Nor is this brief overview intended to be used to limit the claimed subject matter's scope.

Embodiments of the present disclosure provides a system and method for automated evaluation and assignment of fair values to the capital contribution of the license awarded to the entity to operate while avoiding fraud and business failures.

The disclosed embodiment includes a system for wafer handling for semiconductor manufacturing that integrates planar motor technology directly into vacuum transfer.

In one embodiment provided a system for wafer handling for semiconductor manufacturing, including at least one vacuum transfer chamber; at least one planar motor mover unit positioned inside the at least one vacuum transfer chamber; an End-effector attached to the least one planar motor mover unit. The End-effector is configured to travel in any direction inside of the at least one vacuum transfer chamber.

Both the foregoing brief overview and the following detailed description provide examples and are explanatory only. Accordingly, the foregoing brief overview and the following detailed description should not be considered to be restrictive. Further, features or variations may be provided in addition to those set forth herein. For example, embodiments may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present disclosure. The drawings contain representations of various trademarks and copyrights owned by the Applicant. In addition, the drawings may contain other marks owned by third parties and are being used for illustrative purposes only. All rights to various trademarks and copyrights represented herein, except those belonging to their respective owners, are vested in and the property of the Applicant. The Applicant retains and reserves all rights in its trademarks and copyrights included herein, and grants permission to reproduce the material only in connection with reproduction of the granted patent and for no other purpose.

Furthermore, the drawings may contain text or captions that may explain certain embodiments of the present disclosure. This text is included for illustrative, non-limiting, explanatory purposes of certain embodiments detailed in the present disclosure. In the drawings:

FIG. 1 illustrates system for a wafer handling for semiconductor manufacturing that integrates planar motor technology directly into vacuum transfer chambers according to the disclosed embodiments;

FIG. 2 illustrates a vie of motor modules inside the bottom of the chamber according to the disclosed embodiments;

FIG. 3 illustrates a chamber cross-section view according to the disclosed embodiments;

FIG. 4 illustrates a motor module designed to have an outer housing according to the disclosed embodiments. ;

FIG. 5 depicts an ultraclean no Equipment Front End Module (EFEM) Transfer system according to the disclosed embodiments;

FIG. 6 illustrates a single planar motor mover with dual or extended magnetic arrays;

FIG. 7 illustrates a detailed view of the system with the dual or extended array mover, according to the disclosed embodiments;

FIG. 8 illustrates a Planar motor wafer pre-aligner, according to the disclosed embodiments.

### DETAILED DESCRIPTION

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

Accordingly, while embodiments are described herein in detail in relation to one or more embodiments, it is to be understood that this disclosure is illustrative and exemplary of the present disclosure and are made merely for the purposes of providing a full and enabling disclosure. The detailed disclosure herein of one or more embodiments is not intended, nor is to be construed, to limit the scope of patent protection afforded in any claim of a patent issuing here from, which scope is to be defined by the claims and the equivalents thereof. It is not intended that the scope of patent protection be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection is to be defined by the issued claim(s) rather than the description set forth herein.

Additionally, it is important to note that each term used herein refers to that which an ordinary artisan would understand such term to mean based on the contextual use of such term herein. To the extent that the meaning of a term used herein—as understood by the ordinary artisan based on the contextual use of such term—differs in any way from any particular dictionary definition of such term, it is intended that the meaning of the term as understood by the ordinary artisan should prevail.

Regarding applicability of 35 U.S.C. § 112, ¶6, no claim element is intended to be read in accordance with this statutory provision unless the explicit phrase “means for” or “step for” is actually used in such claim element, whereupon this statutory provision is intended to apply in the interpretation of such claim element.

Furthermore, it is important to note that, as used herein, “a” and “an” each generally denotes “at least one,” but does not exclude a plurality unless the contextual use dictates otherwise. When used herein to join a list of items, “or” denotes “at least one of the items,” but does not exclude a plurality of items of the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present disclosure contains headers. It should be understood that these headers are used as references and are not to be construed as limiting upon the subjected matter disclosed under the header.

The present disclosure includes many aspects and features. Moreover, while many aspects and features relate to, and are described in, the context of wafer handling, embodiments of the present disclosure are not limited to use only in this context.

The disclosed system and method that include the following features and elements. The method and apparatus according to the disclosed embodiments, refer to a wafer handling system for semiconductor manufacturing that integrates planar motor technology directly into vacuum transfer chambers. The disclose embodiments may use magnetic levitation to move wafers between process chambers, replacing traditional robotic arms with levitating planar motor “movers” that carry end-effectors for wafer transport.

Some of the key features of the disclosed embodiments include planar motor coils integrated into the vacuum transfer chamber floor, levitating movers with attached end-effectors for wafer transport, modular chamber design allowing for easy system expansion, and non-contact wafer handling throughout the transfer process. These key features eliminate mechanical components that can generate wear particles and significantly reduce contamination risks.

Additionally, the disclosed embodiments provide the following advantages:
1. Increased Throughput: Multiple movers can operate simultaneously within the chamber, potentially increasing overall system throughput.
2. Improved Vacuum Performance: The elimination of complex robotic mechanisms allows for a reduction in chamber volume, enhancing vacuum performance.
3. Enhanced Flexibility: The modular design allows for easy expansion and reconfiguration of the system to meet changing production needs.
4. Reduced Maintenance: With fewer mechanical parts, the system requires less frequent maintenance and experiences less downtime.
5. Space Efficiency: The system allows for more compact and potentially linear layouts, optimizing cleanroom space utilization.
6. Precision Control: Planar motor technology enables highly precise positioning and movement of wafers.

As discussed above, the key innovation of the disclosed method and system is the integration of planar motor technology directly into the vacuum transfer chamber. This approach fundamentally redesigns the wafer handling system, moving away from traditional robotic arms to a more efficient, flexible, and clean transfer mechanism. The use of the motor modules as both functional components and structural reinforcement for the vacuum chamber is a unique aspect of this design.

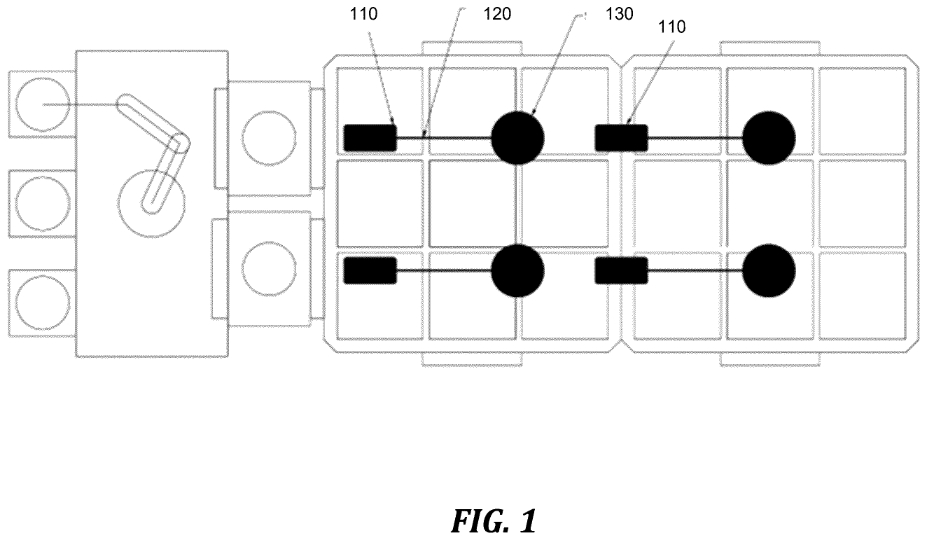

FIG. 1 illustrates system for a wafer handling for semiconductor manufacturing that integrates planar motor technology directly into vacuum transfer chambers according to the disclosed embodiments.

Referring to FIG. 1, the Vacuum robot is completely removed from the system and replaced with planar motor coils 110 directly into a new style vacuum transfer chamber. This would allow levitating planar motor “movers” to directly move around inside the vacuum chamber and have an End-effector 120 attached to them. These components solve the limitations discussed in the background section since they generate no particles, there are no mechanical parts to wear out and the motion of the End-effector 120 would not be limited to a central robot, but instead would be able to travel in any direction inside of the chamber. Multiple chambers may be bolted together since the Movers could continue to travel to any attached chambers that have motor coils installed. Lastly, multiple movers can travel in one chamber at a time increasing throughput of substrate 130.

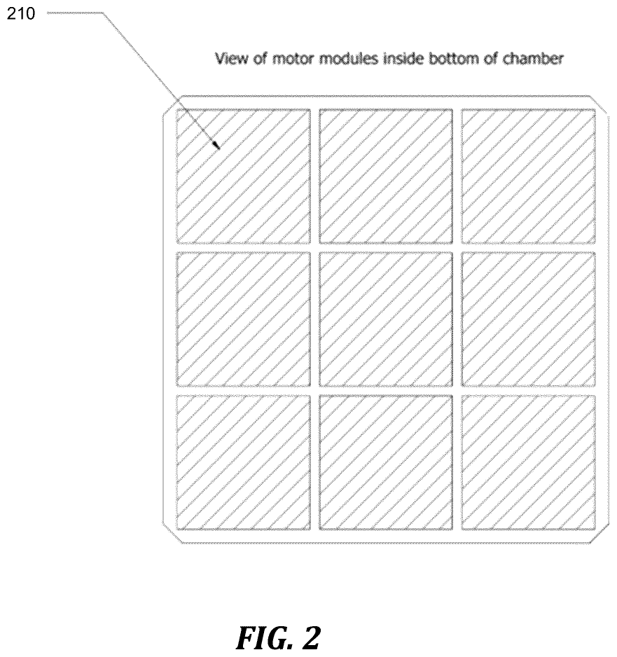

FIG. 2 illustrates a vie of motor modules inside at the bottom of the chamber according to the disclosed embodiments.

Referring to FIG. 2, planar motor coils units 210 are located at the bottom of the chamber.

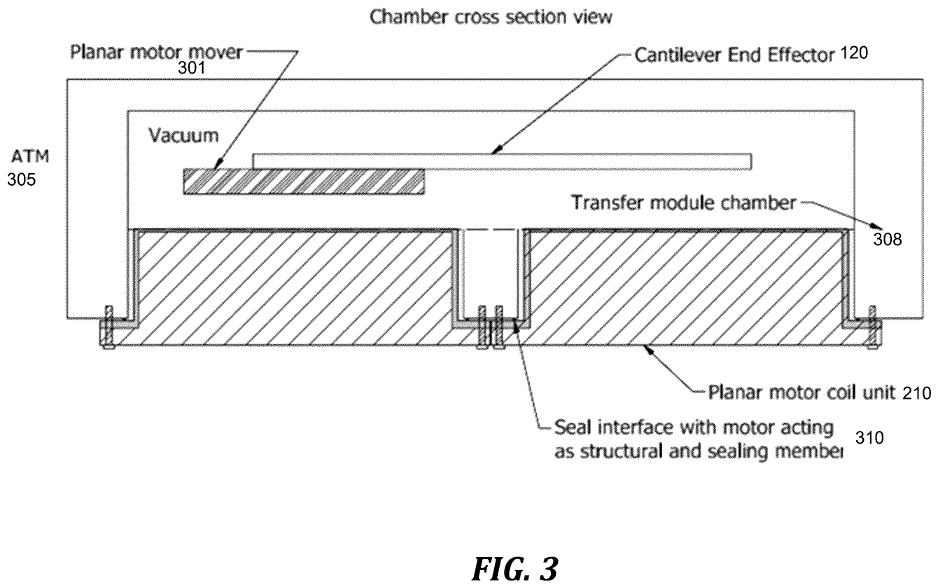

FIG. 3 illustrates a chamber cross-section view according to the disclosed embodiments.

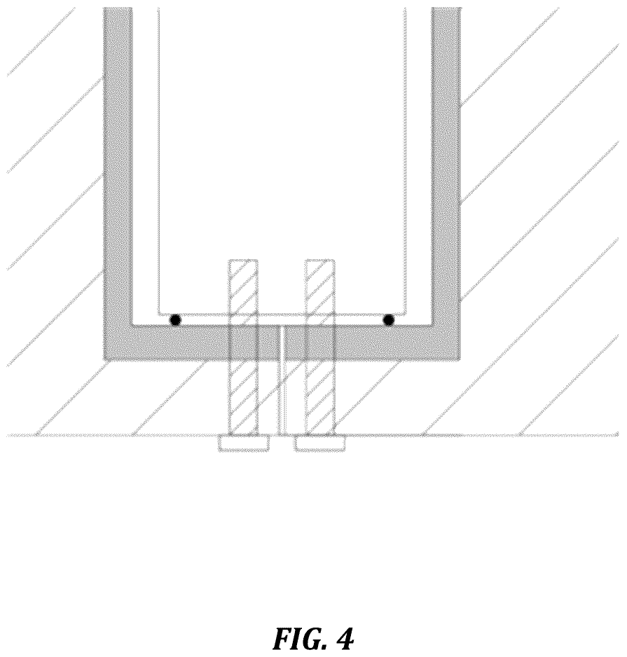

Referring to FIG. 3, a cross section of the vacuum chamber is shown, which unlike a normal vacuum chamber, is not solid but has open pockets machined into it. The edges of pockets on the bottom side may be dressed to have some sort of standard vacuum interface like O-rings. The motor module itself may be designed to have an outer housing (grey area in FIG. 4) that is either a single piece or designed to be vacuum tight. That unit may then be inserted into the open chamber pocket and fixed to the chamber. This provides a vacuum seal and provides a structural reinforcement for the vacuum pressure since the chamber now has large voids. Since there is no need for the robot arms the chamber would be designed so that the bottom of the internal space is aligned to the top of the Planar motor mover unit 301, significantly reducing the volume of the system and increasing vacuum performance. The atmospheric pressure in ATM 305 is provide on the outside. The End-effector 120 is connected to the Planar motor mover unit 301. Multiple Planar motor coil units 210 are located at the bottom of the chamber surrounded by the transfer module chamber 308. The seal interface 310 may be acting as a structural and sealing member.

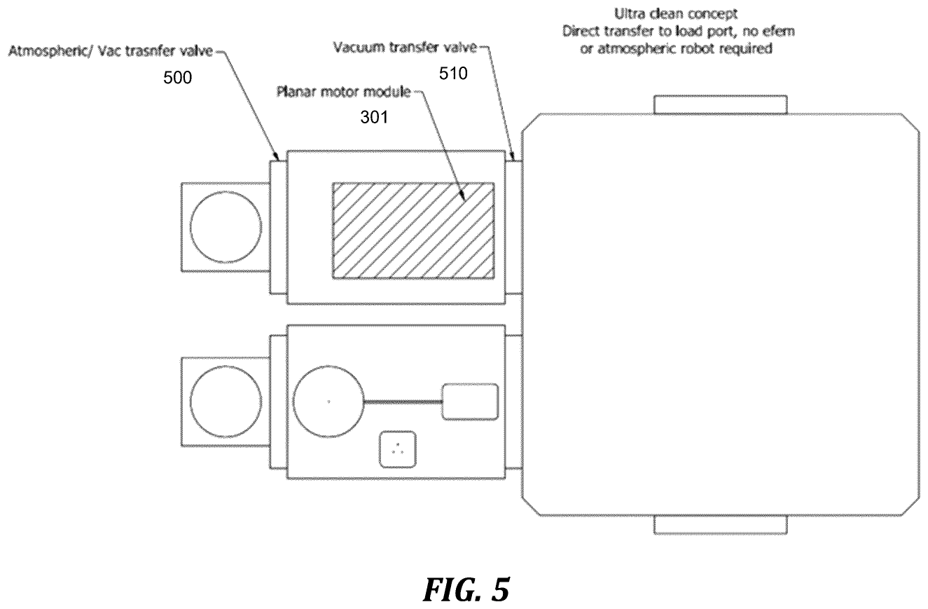

FIG. 5 depicts an ultraclean no Equipment Front End Module (EFEM) Transfer system.

Referring to FIG. 5, since the planar motor 301 allows Wafers to transfer between vacuum to atmospheric sides of the transfer system for the first time a new option is afforded to completely remove the EFEM which is a complicated system that requires serious upkeep and heavy costs. Disclosed herein is a new type of load lock that would allow the End-effector to transfer completely into the load lock with a substrate attached. This allows the system to skip needing an atmospheric robot to unload and reload the Load ports. Vacuum transfer valve 510 and atmospheric/vacuum transfer valve 500 may be used between the chambers.

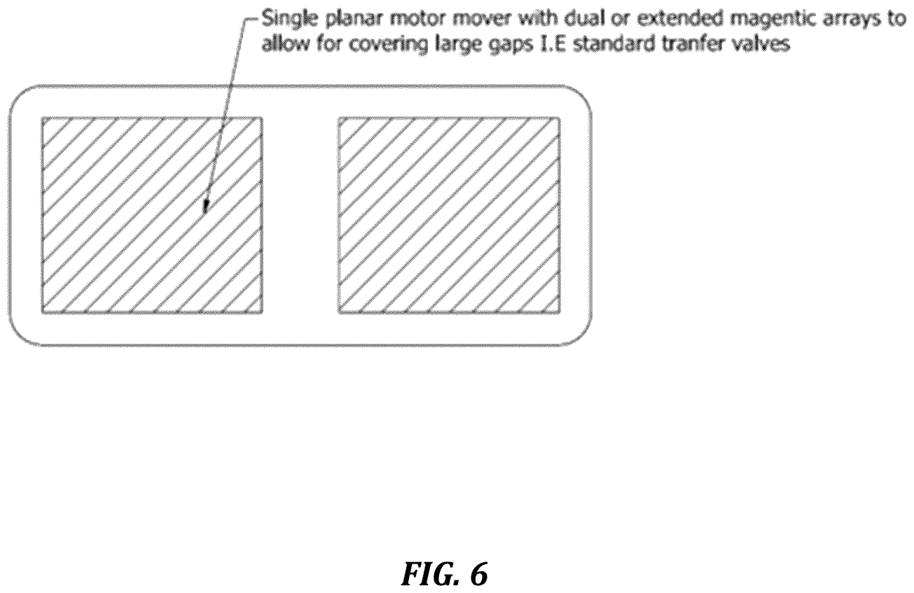

FIG. 6 illustrates a single planar motor mover with dual or extended magnetic arrays.

Referring to FIG. 6, this solution may be required to use industry standard valving. The conventional systems use the transfer valves that are attached between chambers. However, since these cannot have the motors' magnetic arrays in that area, a custom integrated valve that comes down from the top or clear the gap with a standard valve may be used. FIG. 6 depicts a dual array single mover module that allows for the magnets of the first array to cross over the gap to the next motor module. This may allow a standard bottom mount valve, which is used to reduce particles, since the top mount have the moving parts above the substrate.

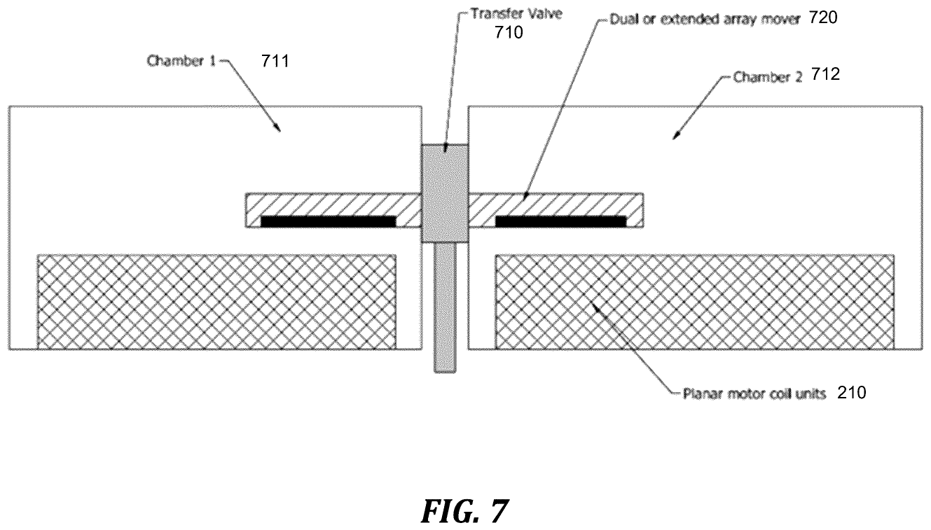

FIG. 7 illustrates a detailed view of the system with the dual or extended array mover, according to the disclosed embodiments.

Referring to FIG. 7, two chambers 711 and 712 may be connected via a transfer valve 710. Planar motor coils units 210 are located at the bottom of both chambers. Each of the chambers 711 and 712 host the dual or extended array movers 720. FIG. 7 also depicts the load lock that moves out of the way but then could travel back under the substrate and pick it off the End-effector, or it could be implemented as its own station.

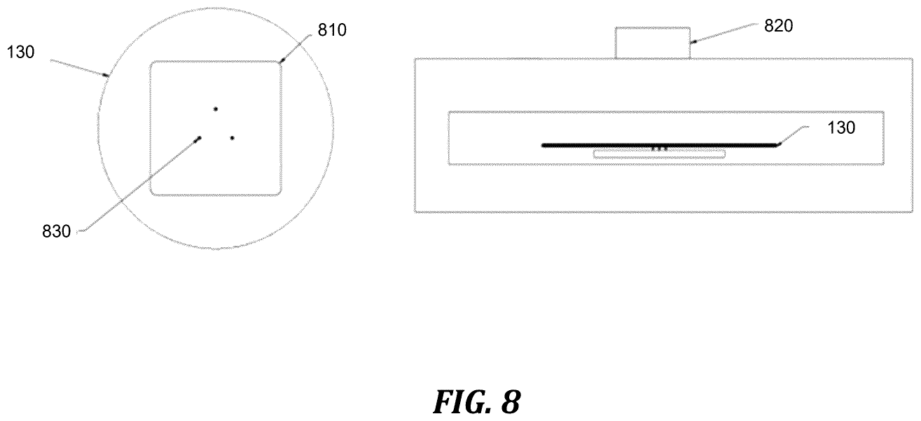

FIG. 8 depicts a Planar motor wafer pre-aligner.

Referring to FIG. 8, with the Planar motor wafer pre-aligner may be integrated into the system by adding a secondary planar motor mover that is smaller than the substrate. Since these movers can rotate, they could move to a location under the substrate and move it to sensor and rotate to measure the alignment and adjust the offset. The mobile wafer aligner puck 810 may use substrate contacts 830 of the substrate 130. An optical measurement device 820 may be used for the substrate 130.

This implementation is advantageous compared to a conventional EFEM equipped with a wafer pre-aligner that is a standalone unit that measures the wafers outer edge by spinning the wafer and looking for the runout and fiducial. It then feeds that information to the robot picking it up to tell it how much offset to pick with so it can get the wafer centered.

In summary, the novel arrangement of the motor modules placed into the chamber to form a sealed surface and structurally reinforce the system is provided. The number of modules inserted may vary by needs. For example, the modules may not need to travel to certain areas to avoid incurring the additional costs of more modules.

All rights including copyrights in the code included herein are vested in and the property of the Applicant. The Applicant retains and reserves all rights in the code included herein, and grants permission to reproduce the material only in connection with reproduction of the granted patent and for no other purpose.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as examples for embodiments of the disclosure.

Insofar as the description above and the accompanying drawing disclose any additional subject matter that is not within the scope of the claims below, the disclosures are not dedicated to the public and the right to file one or more applications to claims such additional disclosures is reserved.

The following is claimed:

1. A system for wafer handling for semiconductor manufacturing, comprising:
at least one vacuum transfer chamber;
at least one planar motor mover unit positioned inside the at least one vacuum transfer chamber;
an End-effector attached to the least one planar motor mover unit,
wherein the End-effector is configured to travel in any direction inside of the at least one vacuum transfer chamber.

2. The system of claim 1, further comprising a plurality of vacuum transfer chambers operatively attached to facilitate movements of a plurality of planar motor mover units within the plurality of vacuum transfer chambers.

3. The system of claim 2, further comprising a plurality of motor coils installed inside the plurality of vacuum transfer chambers.

4. The system of claim 1, wherein the End-effector is configured to be in direct contact with a wafer.

5. The system of claim 1, further comprising a plurality of planar motor magnetic coil units positioned at a bottom of the at least one vacuum transfer chamber.

6. The system of claim 1, further comprising a plurality of planar motor modules placed into the at least one vacuum transfer chamber to form a sealed surface and structurally reinforce the system for the wafer handling.

7. The system of claim 1, wherein the at least one vacuum transfer chamber comprises a plurality of open pockets having edges of the pockets on the bottom side of the at least one vacuum transfer chamber dressed for a vacuum interface comprising an o-ring.

8. The system of claim 1, wherein the at least one planar motor mover unit comprises
an outer housing configured to be vacuum tight.

9. The system of claim 1, wherein a bottom of an internal space of the at least one vacuum transfer chamber is aligned to a top of the at least one planar motor mover unit.

10. The system of claim 1, wherein a vacuum transfer valve is positioned between the at least one planar motor mover unit and the at least one vacuum transfer chamber.

11. The system of claim 1, wherein the at least one planar motor mover unit comprises dual magnetic arrays.

12. The system of claim 1, wherein the at least one planar motor mover unit comprises extended magnetic arrays.

13. The system of claim 1, further comprising a planar motor wafer pre-aligner configured as a mobile wafer aligner puck.

14. The system of claim 13, wherein the planar motor wafer pre-aligner is configured access substrate contact points.

15. The system of claim 13, further comprising an optical measurement device attached to the at least one vacuum transfer chamber for the planar motor wafer pre-aligner.
